(19) United States
(12) Patent Application Publication
(10) Pub. No.: US 2025/0006683 A1
(43) Pub. Date: Jan. 2, 2025

(54) BUMP LANDING WITH BOND WIRES FOR IMPROVED SOLDER WETTING

(71) Applicant: Texas Instruments Incorporated, Dallas, TX (US)

(72) Inventors: John Carlo C Molina, Limay (PH); Boom Rabilas, Angeles (PH); Ray Fredric De Asis, Mabalacat (PH)

(21) Appl. No.: 18/345,065

(22) Filed: Jun. 30, 2023

(51) Int. Cl. H01L 23/00; H01L 23/31; H01L 23/495

(52) U.S. Cl. CPC H01L 24/16; H01L 23/3107; H01L 23/49534; H01L 24/81; H01L 2224/10155; H01L 2224/16245; H01L 2224/81815; H01L 2924/35121

(57) ABSTRACT

An electronic device includes a semiconductor die, a support structure and bond wires, where the semiconductor die has a semiconductor body, a metallization structure over the semiconductor body, and a conductive terminal, the metallization structure includes a top level that extends in a plane of orthogonal first and second directions, the conductive terminal extends away from the plane along an orthogonal third direction, and the support structure has a conductive metal feature with an attachment location. The bond wires are on the attachment location and a package structure at least partially encloses the semiconductor die and a portion of the support structure, where the conductive terminal is soldered to the attachment location of the conductive feature over at least some of the bond wires.

### BACKGROUND

Flip-chip packaging involves soldering terminals of a semiconductor die to a lead frame or package substrate. Reliability of the connection is important for automotive, industrial or other applications and system performance can be impacted by solder wetting during manufacturing, and by solder joint cracking or mold material delamination. Bond line thickness (BLT) is a measure of the solder connection of a die to a lead frame or substrate, and proper solder wetting facilitates solder bonding with the metals of the die terminals and the conductive features of the lead frame or package substrate. Bond line thickness (BLT) is a measure of the bond, and BLT problems such as solder joint cracking or mold material delamination can adversely affect chip level reliability (CLR) for devices having a die flip-chip soldered to a substrate. BLT problems such as solder joint cracking or mold material delamination can adversely affect chip level reliability (CLR) for devices having a die flip-chip soldered to a substrate, for example, if the bond line thickness is too small. Using taller copper bump or conductive terminals on the bottom of the die can mitigate reduced bond line thickness and associated reliability problems, as can using more solder paste and/or refined mold flowing processing, but these approaches add cost and can cause other problems. Separation or delamination of device package molding compound from a lead frame or substrate structures can be addressed by selective plating and/or lead frame roughening techniques to promote lead frame to mold adhesion. However, selective lead frame plating adds manufacturing cost. Moreover, surface roughening can worsen solder wetting even with the use of aggressive flux during soldering, due to growth of copper oxides which act as a diffusion barrier contaminant which can inhibit solder bonding with the terminal and lead frame or substrate metals and prevent proper adhesion for an acceptable solder joint.

### SUMMARY

In one aspect, an electronic device includes a semiconductor die, a support structure and bond wires, where the semiconductor die has a semiconductor body, a metallization structure over the semiconductor body, and a conductive terminal, the metallization structure includes a top level that extends in a plane of orthogonal first and second directions, the conductive terminal extends away from the plane along an orthogonal third direction, and the support structure has a conductive metal feature with an attachment location. The bond wires are on the attachment location and a package structure at least partially encloses the semiconductor die and a portion of the support structure, where the conductive terminal is soldered to the attachment location of the conductive feature over at least some of the bond wires.

In another aspect, a support structure includes a conductive metal feature with an attachment location and bond wires on the attachment location.

In a further aspect, a method of fabricating an electronic device includes forming bond wires on an attachment location of a conductive feature of a support structure and soldering a conductive terminal of a semiconductor die to the attachment location of the conductive feature over at least some of the bond wires.

### BRIEF DESCRIPTION OF THE DRAWINGS

FIG. 1 is a sectional side elevation view of a packaged electronic device with a semiconductor die flip chip soldered to a multilevel package substrate with bond wires on top metal attachment locations of the multilevel package substrate.

FIG. 1A is a partial top plan view of the multilevel package substrate taken along line 1A-1A of FIG. 1 showing bond wires formed in mesh arrangements on two example attachment locations.

FIG. 1B is a partial sectional side view taken along line 1B-1B of FIG. 1A showing a bond wire on a top metal attachment location of the multilevel package substrate with a conductive die terminal soldered to a first height distance above the top metal attachment location.

FIG. 1C is a partial sectional side view of another example with a bond wire on a top metal attachment location of the multilevel package substrate with a conductive die terminal soldered to a smaller second height distance above the top metal attachment location and touching the bond wire.

FIG. 1D is a partial top plan view of the multilevel package structure showing further example bond wires formed in an overlapping mesh arrangement on an example attachment location.

FIGS. 2 and 2A are sectional side elevation views of another example packaged electronic device with a semiconductor die flip chip soldered to a lead frame with bond wires on top metal attachment locations of the lead frame.

FIG. 3 is a flow diagram showing a method of fabricating an electronic device.

FIGS. 4-10 are partial sectional side elevation views showing the electronic device of FIGS. 2 and 2A undergoing fabrication processing according to the method of FIG. 3.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately.” or “substantially” preceding a value means+/−10 percent of the stated value.

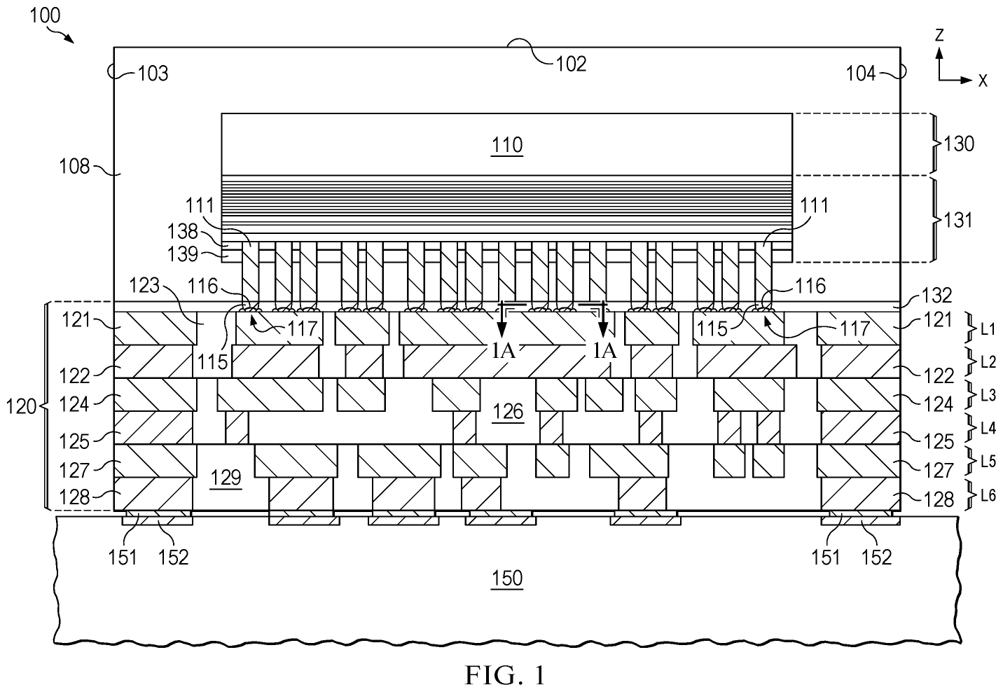

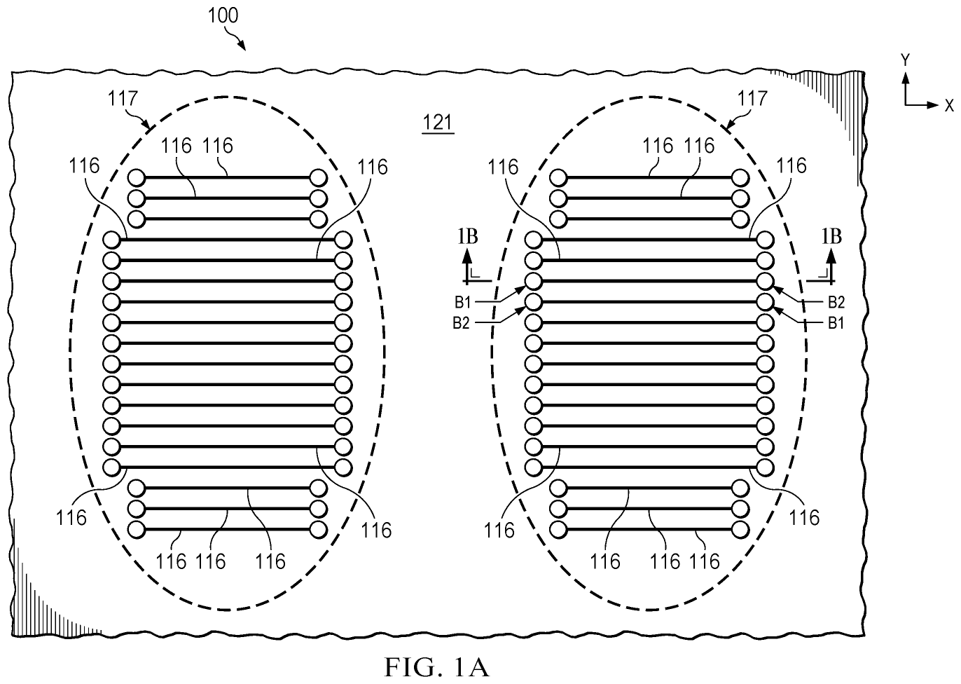

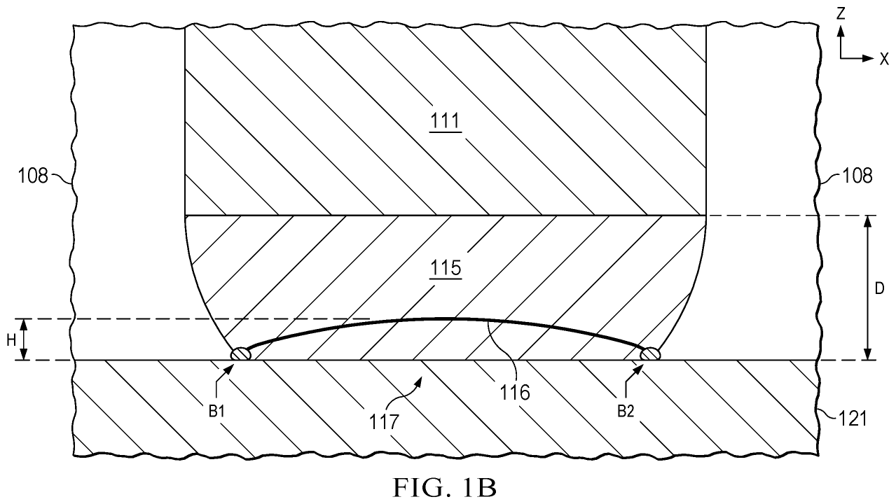

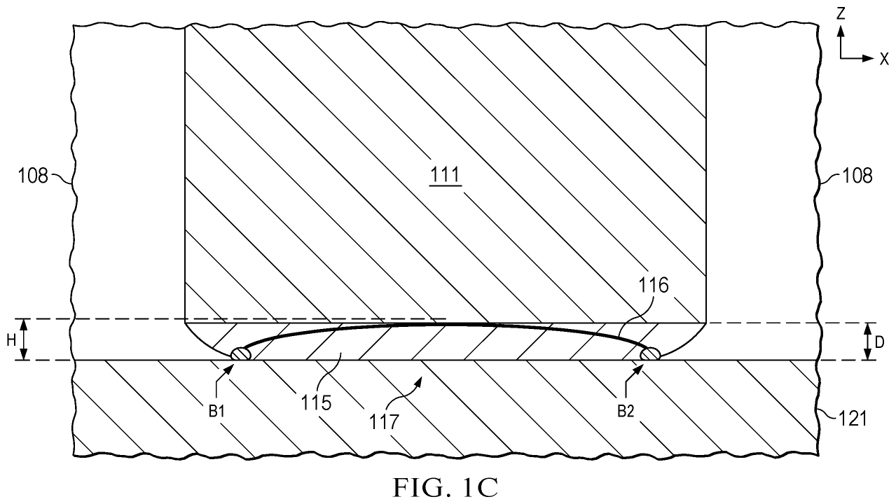

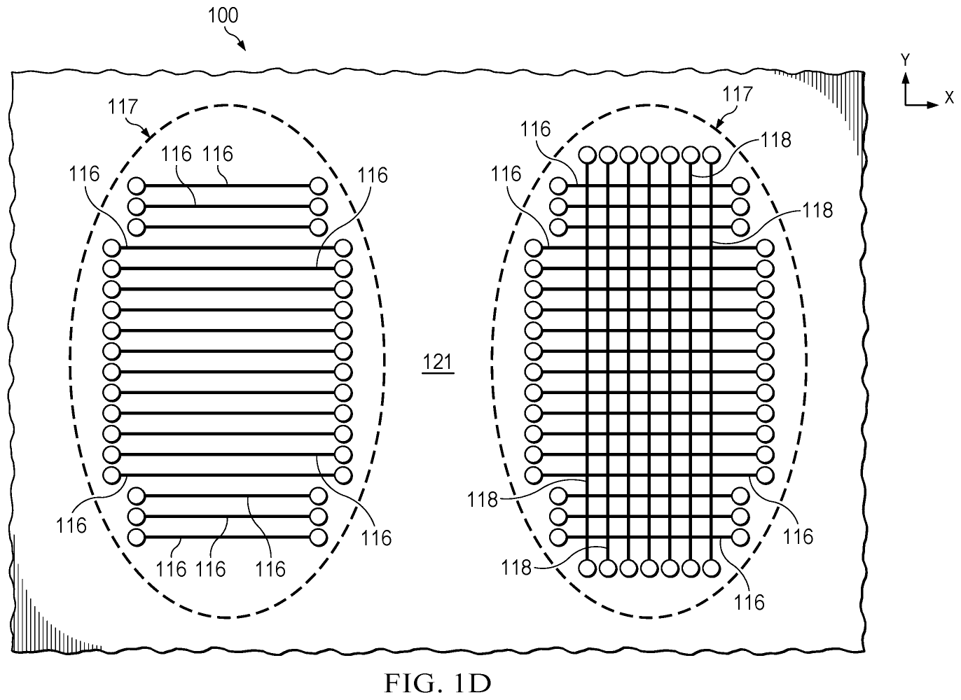

Referring initially to FIGS. 1-1D, FIG. 1 shows a side view of a packaged electronic device 100 with a semiconductor die 110 with conductive terminals 111 flip chip soldered to a support structure 120 (e.g., a multilevel package substrate) with bond wires 116 on top metal attachment locations 117 of the multilevel package substrate 120, FIG. 1A shows a partial sectional top view of the multilevel package substrate taken along line 1A-1A of FIG. 1, and FIG. 1B shows a partial sectional side view taken along line 1B-1B of FIG. 1A of a bond wire 116 on a top metal attachment location 117 with a conductive die terminal 111 soldered to a first height distance D above the top metal attachment location 117. FIG. 1C shows a partial sectional side view of another example with a bond wire 116 on a top metal attachment location 117 with a conductive die terminal 111 soldered to a smaller second height distance D above the top metal attachment location 117 with the terminal 111 touching the bond wire 116, and FIG. 1D shows a partial top view of the support structure 120 (e.g., multilevel package structure) with further example bond wires 116 and 118 formed in an overlapping mesh arrangement on an example attachment location 117.

The electronic device 100 and other examples provide top metal attachment locations 117, also referred to as bump landings, with bond wires to facilitate improved solder wetting for flip-chip solder attachment of semiconductor dies 110 onto lead frame support structures or multilevel package substrate support structures 120 to enhance chip level reliability and reduce the risk of solder joint cracking while allowing for lead frame or substrate metal roughening for robust protection against delamination during manufacturing and end use of packaged electronic devices 100. Described examples have reinforced metal attachment locations 117 (referred to as bump landing pads) for support structures (e.g., lead frames, multilevel package substrates, etc.) with multiple bond wires 116, for example, that can form a mesh structure covering all or part of the metal attachment locations 117. The described examples provide an improved structure to couple conductive die terminals 111 (e.g., copper or other metal posts, pillars, solder bumps, etc.) mechanically and electrically to corresponding metal attachment locations 117 of a support structure 120 via solder 115. The solder 115 in one example is applied to the die terminals 111 prior to die attach processing, such as by printing, dipping, plating, etc. In other implementations, the solder 115 can be applied to the metal attachment locations 117 after wire bonding and prior to die placement. The bond wires 116, whether formed as an overlapping wire bond mesh structure or a non-overlapping arrangement, creates a structure where the solder 115 can wet and enhance BLT and adherence strength for improved component level reliability and electronic device performance.

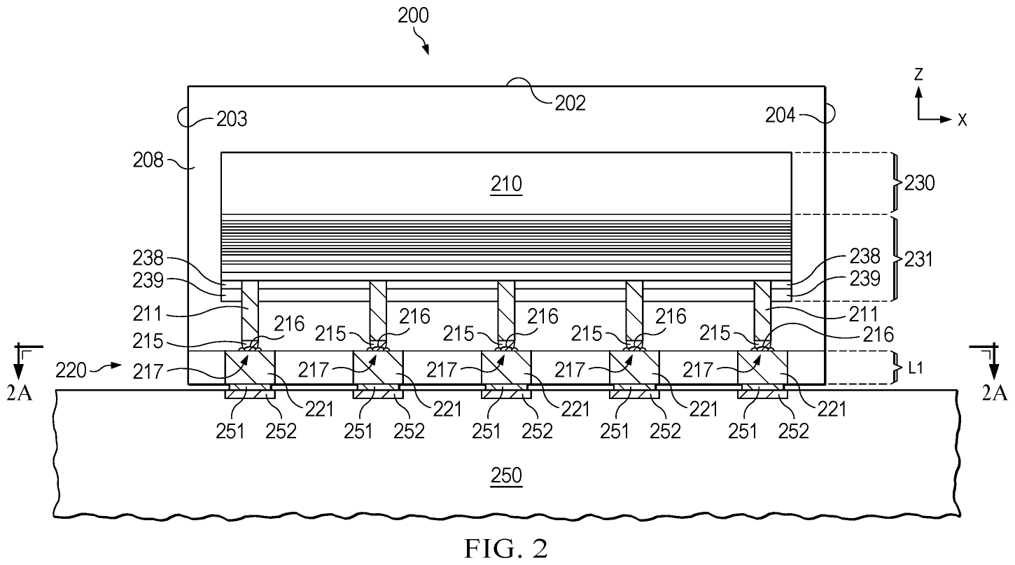

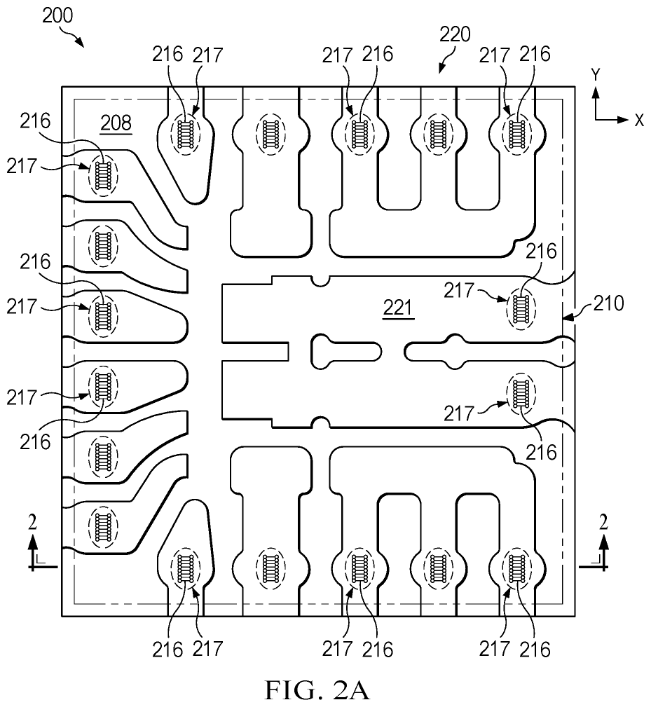

The illustrated electronic device 100 is a flip-chip chip scale package (FCCSP) device. Other device package forms and types can be used in other implementations, such as having leads formed from a starting lead frame and internal bond wire connections (e.g., FIGS. 2 and 2A below), flip chip ball grid array (FCBGA) devices, etc. FIG. 1 shows the electronic device 100 installed in a system, such as a smart phone, laptop or desktop computer, a tablet, an automotive system, an industrial system, etc. The electronic device 100 is shown in an example position or orientation in a three-dimensional space with a first direction X, a perpendicular (orthogonal) second direction Y (into the page, not numerically designated in FIGS. 1, 1B, and 1C), and a third direction Z that is perpendicular (orthogonal) to the respective first and second directions X and Y. Structures or features along any two of these directions are orthogonal to one another. As shown in FIG. 1, the electronic device 100 has a first (e.g., bottom) side and an opposite second (e.g., top) side 102, which are spaced apart from one another along the third direction Z, as well as laterally opposite third and fourth sides 103 and 104 that are spaced apart from one another along the first direction X and opposite fifth and sixth sides (not shown) that are spaced apart from one another along the second direction Y. The sides in one example have substantially planar outer surfaces. In other examples (not shown), one or more of the sides of the electronic device 100 have curves, angled features, or other non-planar surface features. The electronic device 100 has a package structure 108 (FIGS. 1, 1B and 1C), such as a molded plastic structure that forms all or a portion of the second side and upper portions of the lateral sides.

The semiconductor die 110 is partially enclosed by the package structure 108 and the die 110 is flip chip attached (e.g., by solder connections) to the support structure 120 (e.g., multilevel package substrate). The molded package structure 108 extends onto and encloses the semiconductor die 110 and a portion of a top side of the support structure 120. The semiconductor die 110 has generally planar top and bottom sides and the conductive terminals 111 extend downward along the bottom side. The semiconductor die 110 includes one or more electrical circuit components (e.g., transistors, resistors, capacitors, diodes, etc., not shown) as well as the conductive terminals 111 (FIGS. 1 and 1A). At least some of the conductive terminals 111 provide circuit connections to interconnect other external devices and/or components to a circuit of the electronic device 100.

The conductive terminals 111 in the illustrated examples are conductive metal pillars or posts (e.g., copper, etc.) that extend outward from the bottom side of the semiconductor die 110. This facilitates flip-chip die attachment and soldering to form electrical connections to the circuitry of the electronic device 100. The conductive terminals 111 in one example each have a solder cap 115 applied to the ends thereof, for example, by electroplating during a bumping process or other suitable dipping, printing or other process to allow flip-chip attachment and thermal reflow to make electrical and mechanical connections thereto. In one example for flip chip chip scale packages, the terminals 111 are copper pillars formed by electroplating in a bumping process, which is followed by electroplating of the solder portions 115 on top of the copper pillar during the wafer bumping process. For FCBGAs, the flip chip side substrate pad can have solder as well as other finishes like OSP, ENEPIG, etc. The conductive terminal 111 (e.g., bump interconnect) formed on a processed wafer in one example is or includes copper and a solder cap, which is subsequently attached to the package substrate 120 to form electrical interconnections of a circuit of the electronic device 100.

As best shown in FIG. 1, the illustrated example support structure 120 is a multilevel package substrate (referred to hereinafter as a multilevel package substrate). In other implementations, a single level substrate or lead frame (e.g., FIG. 2 below) can be used and/or a different type of substrate can be used. The multilevel package substrate 120 includes multiple dielectric layers or levels (e.g., electrical insulators) with patterned conductive features formed thereon and therebetween to provide circuit signal and power routing for the circuitry of the electronic device 100. The multilevel package substrate 120 can have any number of two or more levels with respective patterned conductive metal features. As best shown in FIG. 1, the illustrated example has six levels formed in a stacked arrangement (e.g., a stack) including a top or first level L1, a second level L2 below the first level L1, a third level L3 below the second level L2, a fourth level L4 below the third level L3, a fifth level L5 below the fourth level L4, and a bottom or sixth level L6 below the fifth level L5. The first level L1 has patterned first conductive features 121 and extends in a first plane (e.g., an X-Y plane) of the first and second directions X and Y. The second level L2 has patterned second conductive features 122 in a second X-Y plane. A dielectric material 123 extends between the conductive features 121 and 122 within and between the respective first and second levels L1 and L2.

The third level L3 has patterned third conductive features 124 in a third X-Y plane, the fourth level L4 has patterned fourth conductive features 125 in a fourth X-Y plane, and dielectric material 126 extends between the conductive features 124 and 125 within and between the respective levels L3 and L4. The fifth level L5 has patterned fifth conductive features 127 in a fifth X-Y plane, the sixth level L6 has patterned sixth conductive features 128 in a sixth X-Y plane, and dielectric material 129 extends between the conductive features 127 and 128 within and between the respective fifth and sixth levels L5 and L6.

The illustrated example has dielectric layers 123, 126, and 129 that each extend in two adjacent levels. In other examples, each level can have an associated dielectric layer or different numbers and configurations of dielectric layers can be used. The illustrated example has one layer of conductive metal features in each level. In other examples, one or more levels can include two or more layers or sublevels of conductive metal features, such as trace and via structures in a given level. The conductive features 121, 122, 124, 125, 127, and 128 in one example are or include a conductive metal, such as copper, aluminum, etc.

As best shown in FIG. 1, the semiconductor die 110 has a semiconductor body 130 (e.g., silicon or other suitable semiconductor material) and a metallization structure 131 that extends over the semiconductor body 130. The metallization structure 131 extends from a protective overcoat layer 138 toward the semiconductor body 130 proximate the lateral sides of the semiconductor die 110. The protective overcoat layer 138 extends over bottom side of the metallization structure 131. In one example, the protective overcoat layer 138 is or includes an inorganic-based passivation material, such as a silicon nitride (SiN), silicon oxynitride (SiOₓN_{y}), or silicon dioxide (SiO₂). An organic-based passivation layer, such as a polyimide layer 139 extends over the protective overcoat layer 138, and the conductive terminals 111 extend from the metallization structure 131 through the protective overcoat layer 138 and the polyimide layer 139.

FIG. 1 shows a system implementation that includes the FCCSP electronic device 100 installed on a circuit board 150 in the system of FIG. 1, with respective ones of the substrate leads (e.g., features 128) soldered to provide mechanical and electrical connections to conductive metal board pads 152 of the circuit board 150 via solder 151. The circuit board 150 can be a component of a smart phone, laptop or desktop computer, a tablet, an automotive system, an industrial system, or other type of host system.

To facilitate solder wetting and enhance the attachment of the semiconductor die 110 to the multilevel package substrate 120 by flip-chip soldering, the multilevel package substrate 120 has bond wires 116 on the attachment locations 117 on the top sides of corresponding top conductive metal features 121 of the first level L1 as shown in FIGS. 1-1D. In one example, at least some of the bond wires 116 are approximately parallel to one another as shown in FIGS. 1A and 1D, although not a requirement of all possible implementations. As shown in FIGS. 1B and 1C, moreover, the conductive terminals 111 in one example are soldered to the attachment location 117 of the corresponding conductive feature 121 over at least some of the bond wires 116. In this example, the bond wires 116 are approximately parallel to one another and extend approximately along the first direction X. Parallel or approximately parallel orientation of two or more of the bond wires 116 can advantageously facilitate faster wire bonding processing during fabrication. In other implementations, parallel orientation is not required, and individual bond wires or groups thereof can be at any angular relationship, independent of the illustrated directions X and/or Y.

As further shown in FIGS. 1A-1C, the individual bond wires 116 have a first end with a first bond B1 connected to a first portion of the attachment location 117, and a second end with a second bond B2 connected to a second portion of the attachment location 117. In one example, the first bond B1 is a ball bond and the second bond B2 is a stitch bond, although any suitable bond types and forms can be used. In the example of FIG. 1A, the wire bonding process can be shortened by suitable wire bonding tool programming or operation to alternately form a first bond wire from left to right with a first ball bond B1 on the left and a second stitch bond B2 on the right, and the next lower bond wire 116 can be thereafter formed from right to left with a first ball bond B1 on the right and a second stitch bond B2 on the left, for example, to reduce the translation distance required of the wire bonding tool and reduce processing time.

FIG. 1D shows an example attachment location having first bond wires 116 extending generally along the first direction X as well as second bond wires 118 extending approximately orthogonally along the second direction Y, where respective first and second ones of the bond wires 116 and 118 overlap one another. The overlapping need not be orthogonal, and any angular relationship cab be used in which a portion of a first bond wire 116 overlaps (i.e., overlies or at least partially extends above) a portion of a second bond wire 118. This example provides bond wires 116 and 118 formed in an overlapping mesh arrangement in an example attachment location 117. In various implementations, the overlapping can include contact between two bond wires 116 and 118, although non-contacting overlapping orientations are possible, as are implementations that include combinations of contacting and non-contacting overlapping bond wires 116, 118.

As further shown in FIGS. 1B and 1C, a given conductive terminal 111 may be soldered to the associated attachment location 117 of the conductive metal feature 121 in a spaced apart relationship to one or more of the associated bond wires 116, 118. The bond wire 116 in the example of FIG. 1B is formed to a height distance H by a wire bonding tool (not shown) and the flip-chip attach soldering processing results in the bottom side of the conductive terminal 111 being spaced apart from the top side of the conductive feature 121 by a spacing distance D, where D is greater than the bond wire height H such that the conductive terminal 111 is spaced apart from (i.e., does not contact) the bond wire 116. FIG. 1C shows another example, in which the conductive terminal 111 contacts and at least partially compresses the bond wire 116, such that the bottom side of the conductive terminal 111 is spaced from the top side of the conductive feature 121 by a spacing distance D that is less than the starting bond wire height distance H. Combinations are possible, for example, in which a given conductive terminal 111 touches one or more bond wires 116, 118 and is spaced apart from one or more other bond wires 116, 118.

In some examples, the attachment location 117 of the conductive metal feature 121 has a roughened surface, for example, created by chemical processing, laser ablation or other suitable process (selective or blanket processing, such as during substrate or lead frame manufacturing), although not a requirement of all possible implementations. The use of bond wires 116 and/or 118 in the attachment location 117 can provide benefits with respect to solder wetting and CLR enhancement for bare copper surfaces which have not undergone any surface roughening processing as well as for attachment locations 117 having a roughened surface.

FIGS. 2 and 2A show sectional side views of another example system with a packaged electronic device 200 having a semiconductor die flip chip soldered to a lead frame support structure 220 with bond wires 216 on top metal attachment locations 217 of the lead frame. The electronic device 200 and the system have components, features, dimensions and structures 202-204, 208, 210, 211, 215, 217, 230-232, 238, 239, 250, 251 and 252 that generally correspond with the respective features and structures 102-104, 108, 110, 111, 115, 117, 130-132, 138, 139, 150, 151 and 152 described above in connection with the electronic device examples 100 of FIGS. 1-1D unless otherwise indicated. In this example, the support structure 220 is a lead frame 220 that includes conductive metal features 221. Although described as a lead frame, the conductive metal structures 221 can be separate from one another, for example, as a result of cutting or lead frame trimming operations during manufacturing starting from a beginning lead frame panel array. The lead frame 220 can be a flat patterned metal structure as shown or can have half-etch or bent portions (not shown) or combinations thereof in different examples, and the attachment location 117 of the conductive metal features 121 may have a roughened surface, although not a requirement of all possible implementations. As shown in FIGS. 2 and 2A, the lead frame 220 has bond wires 216 on the attachment locations 217 on the top sides of corresponding top conductive metal features 221 to facilitate solder wetting and enhance the attachment of the semiconductor die 210 to the lead frame 220 by flip-chip soldering and may provide one or more of the benefits and/or advantages described above in connection with FIGS. 1-1D.

In one example, at least some of the bond wires 216 are approximately parallel to one another as shown in FIG. 2A, although not a requirement of all possible implementations. The conductive terminals 211 in one example are soldered to the attachment location 217 of the corresponding conductive feature 221 over at least some of the bond wires 216. In this example, the bond wires 216 are approximately parallel to one another and extend approximately along the first direction X as shown in FIG. 2A, which can facilitate faster wire bonding processing during fabrication. In other implementations, parallel orientation is not required, and individual bond wires or groups thereof can be at any angular relationship, independent of the illustrated directions X and/or Y. The individual bond wires 216 have a first end with a first bond (not numerically referenced in FIGS. 2 and 2A) connected to a first portion of the attachment location 217, and a second end with a second bond connected to a second portion of the attachment location 217.

The first and second bonds can be ball bonds, stitch bonds and/or any suitable bond type and form, or combinations thereof. One or more of the bond wires 116 can overlap all or a portion of one or more other bond wires, and the overlapping can be orthogonal or non-orthogonal, for example, as described above in connection with FIG. 1D. As discussed above in connection with FIGS. 1B and 1C, moreover, a given conductive terminal 211 may be soldered to the associated attachment location 217 of the conductive metal feature 221 in a spaced apart relationship to one or more of the associated bond wires 216 and/or as given conductive terminal 211 can contact one or more of the bond wires 216, and combinations are possible, for example, in which a given conductive terminal 211 touches one or more bond wires 216 and is spaced apart from one or more other bond wires 216.

In some examples, the attachment location 217 of the conductive metal feature 221 has a roughened surface, for example, created by chemical processing, laser ablation or other suitable process (selective or blanket processing, such as during lead frame manufacturing), although not a requirement of all possible implementations. The use of bond wires 216 in the attachment location 217 can provide benefits with respect to solder wetting and CLR enhancement for bare copper surfaces which have not undergone any surface roughening processing as well as for attachment locations 217 having a roughened surface.

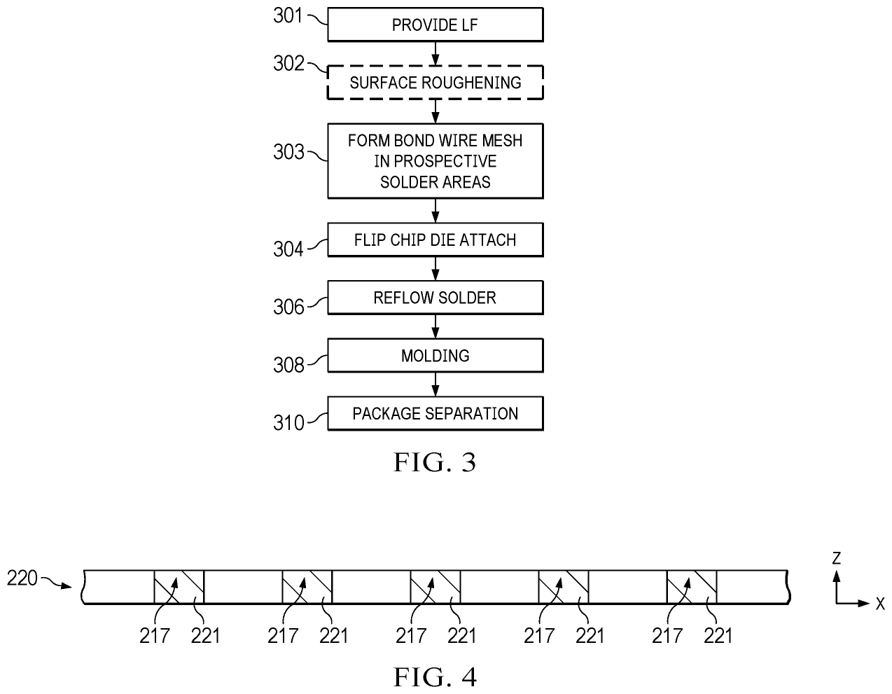

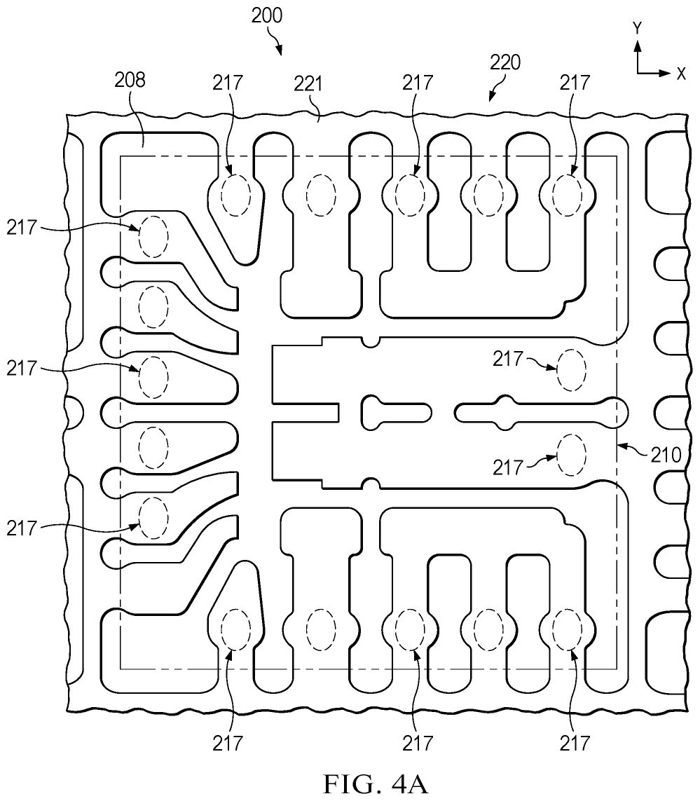

Referring now to FIGS. 3-10, FIG. 3 shows a method 300 of fabricating an electronic device and FIGS. 4-10 show the electronic device 200 undergoing fabrication processing according to the method 300. At 301 in FIG. 3, a lead frame, multilevel package substrate (e.g., 120 above) or other suitable support structure is fabricated or otherwise provided. FIGS. 4 and 4A show respective side and top views of one example of a starting lead frame panel array 220 with rows and columns of unit areas that each include conductive features 221, some of which have one or more attachment locations 217.

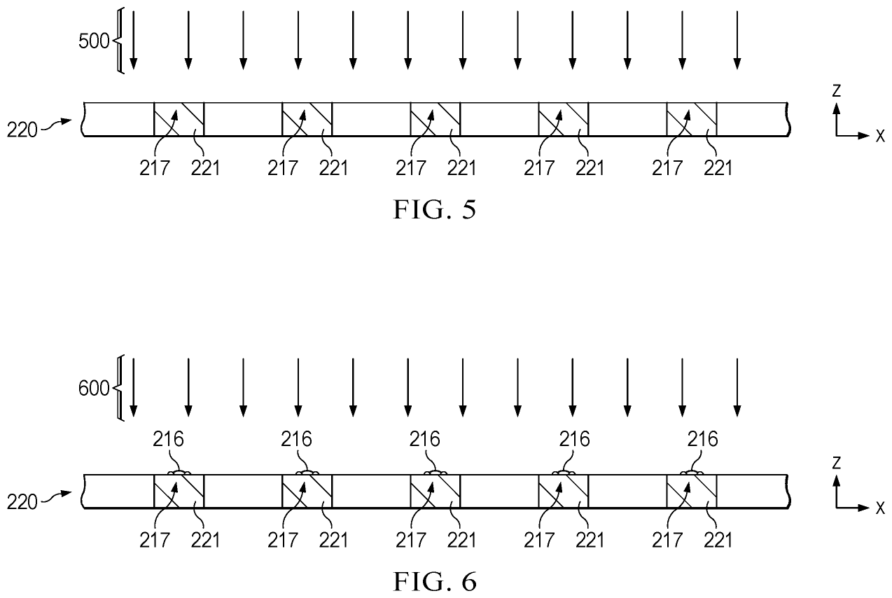

At 302, one implementation of the method 300 includes optional roughening a surface of the attachment location 217 of one or more conductive features 221. FIG. 5 shows one example, in which a chemical or mechanical surface roughening process 500 is performed that roughens a surface of the attachment location 217 (e.g., at least along all or portions of the top side) of one or more conductive features 221. In another implementation, the surface roughening at 302 is omitted.

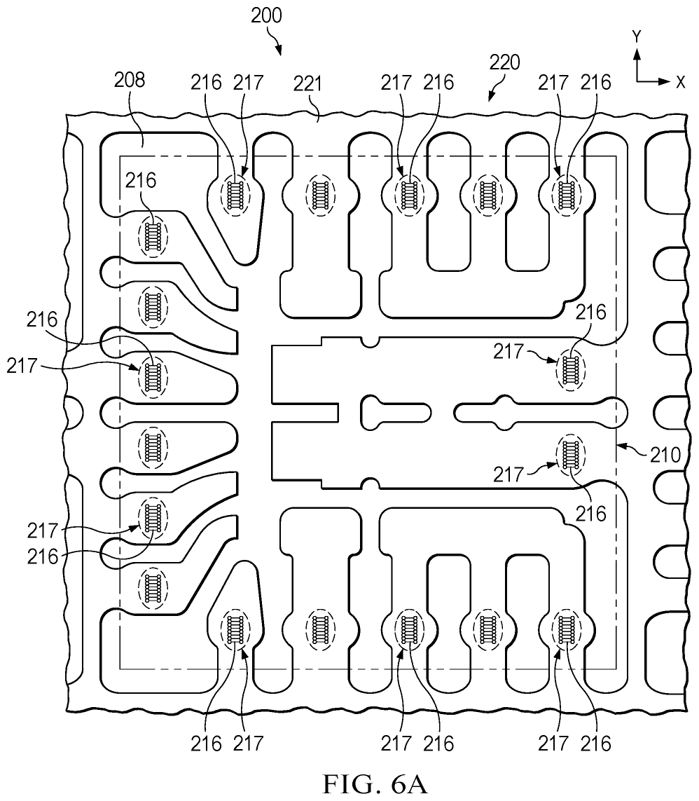

At 303 in FIG. 3, the method 300 includes wire bonding on the lead frame support structure 220 before flip-chip die attach processing. FIG. 6 shows one example, in which a wire bonding process 600 is performed that forms the bond wires 216 on the attachment locations 217 of at least one of the conductive features 221 of the support structure 220. FIG. 6A shows a top view of the lead frame panel array 220 after wire bonding at 303, with the prospective die position indicated as 210 in dashed line in the figure. In one example, the bond wire formation at 303 includes overlapping first and second ones of the bond wires 216, although not a requirement of all possible implementations.

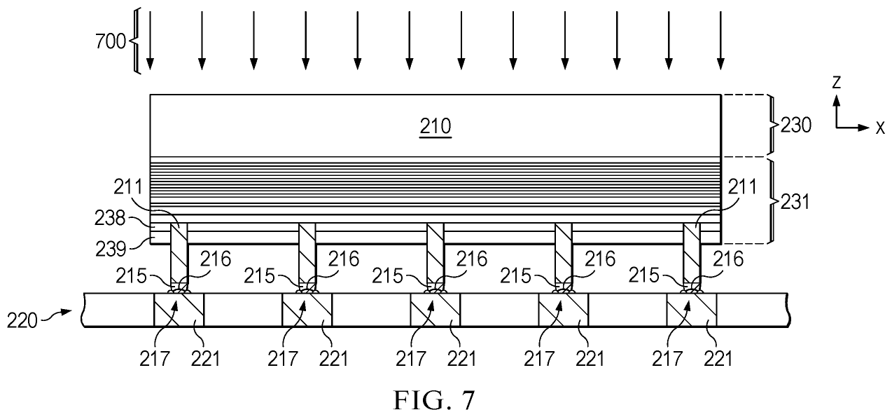

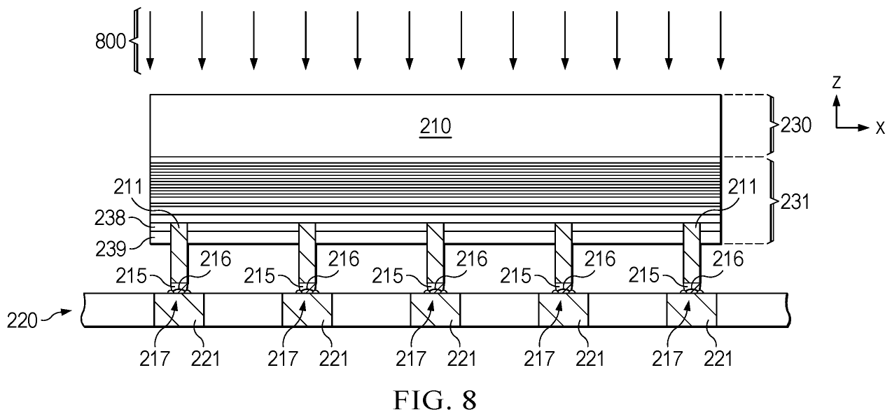

The method 300 continues with flip-chip die attach processing at 304 and 306 in FIG. 3. FIG. 7 shows one example, in which a flip-chip die attach process 700 is performed using the wire bonded lead frame panel array with unit areas corresponding to prospective electronic devices 200. The die attach process 700 in one example includes dipping or otherwise providing the solder portions 215 on the ends of the conductive terminals 211 of individual semiconductor dies 210, and subsequent engagement of the solder portions 215 with respective ones of the attachment locations 217 of one or more of the conductive features 221 of the lead frame panel array 220 in each unit area of the panel array, for example, using automated pick and place equipment (not shown). The die attach process 700 in one example further includes thermal processing by a thermal reflow process 800 in FIG. 8 to reflow the solder portions 215 and create solder joints between the individual conductive terminals 211 of the semiconductor die 210 and respective ones of the conductive features 221.

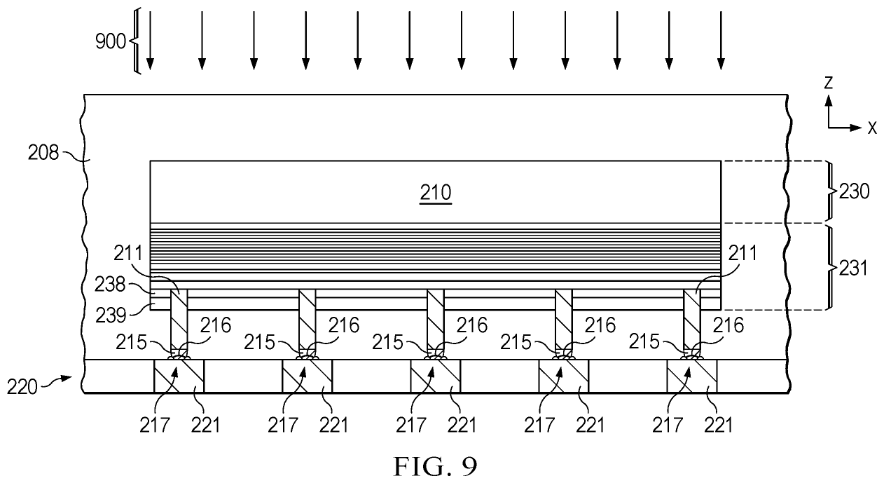

The method 300 continues at 308 in FIG. 3 with package structure formation. In one example, the processing at 308 includes molding operations to form the molded package structure 208 in individual unit areas or groups thereof in the panel array structure. FIG. 9 shows one example, in which a molding process 900 is performed that forms the package structure 208. In one implementation, the molding at 308 can be performed using any suitable molding equipment (not shown). In one implementation, a single mold cavity can be used for an entire panel array or multiple cavities can be used for individual unit areas thereof or groups of unit areas, such as column-wise mold cavities, or combinations thereof. The package structure 208 in one example at least partially encloses the semiconductor die 210 and upper portions of the support structure 220 in each unit area of the panel array. In certain examples, the molding process 900 can include separate formation of multiple molded portions of a package structure, such as initial mold underfill formation, followed by a subsequent top molding process, or the molding at 308 creates a mold underfill followed by attachment of a metal lid (not shown) over at least a portion of a top side of the semiconductor die 210 without forming a second top mold structure (not shown).

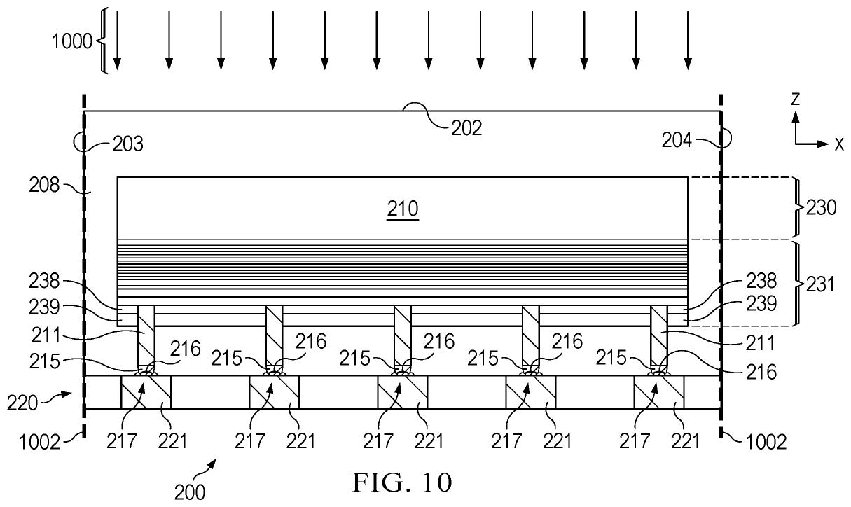

The method 300 in one example also includes package separation at 310 in FIG. 3 to separate individual packaged electronic devices 200 from the processed starting lead frame panel array structure, for example, to form strip or panel array based flip-chip chip scale package (FCCSP) devices (not shown). FIG. 10 shows one example, in which a saw cutting separation process 1000 is performed that separates individual packaged electronic devices 200 from the processed panel array structure by cutting along lines 1002. Any suitable cutting or separation process can be used, including without limitation saw cutting, laser cutting, chemical etching, etc. or combinations thereof. In certain examples, the method 300 can also include final device testing after package separation at 310. In certain implementations, the package separation processing at 310 can be omitted, for example, to form certain flip-chip ball grid array (FCBGA) devices.

Modifications are possible in the described examples, and other implementations are possible, within the scope of the claims.

What is claimed is:

1. An electronic device, comprising:
a semiconductor die having: a semiconductor body; a metallization structure over the semiconductor body; and a conductive terminal, the metallization structure including a top level that extends in a plane of orthogonal first and second directions, the conductive terminal extending away from the plane along a third direction that is orthogonal to the first and second directions; and
a support structure having a conductive metal feature with an attachment location; and
bond wires on the attachment location; and
a package structure that at least partially encloses the semiconductor die and a portion of the support structure;
wherein the conductive terminal is soldered to the attachment location of the conductive feature over at least some of the bond wires.

2. The electronic device of claim 1, wherein the support structure is a multilevel package substrate having first and second levels in respective first and second planes of the first and second directions in a stack along the third direction Z, the first level including the conductive metal feature.

3. The electronic device of claim 2, wherein first and second ones of the bond wires overlap one another.

4. The electronic device of claim 1, wherein the support structure is a lead frame that includes the conductive metal feature.

5. The electronic device of claim 4, wherein the attachment location of the conductive metal feature has a roughened surface.

6. The electronic device of claim 5, wherein first and second ones of the bond wires overlap one another.

7. The electronic device of claim 4, wherein first and second ones of the bond wires overlap one another.

8. The electronic device of claim 1, wherein first and second ones of the bond wires overlap one another.

9. The electronic device of claim 1, wherein the attachment location of the conductive metal feature has a roughened surface.

10. A support structure, comprising
a conductive metal feature with an attachment location; and
bond wires on the attachment location.

11. The support structure of claim 10, wherein each bond wire has a first end with a first bond connected to a first portion of the attachment location, and a second end with a second bond connected to a second portion of the attachment location.

12. The support structure of claim 11, wherein the attachment location of the conductive metal feature has a roughened surface.

13. The support structure of claim 12, wherein first and second ones of the bond wires overlap one another.

14. The support structure of claim 11, wherein first and second ones of the bond wires overlap one another.

15. The support structure of claim 10, wherein first and second ones of the bond wires overlap one another.

16. The support structure of claim 10, wherein the support structure is a multilevel package substrate having first and second levels in respective first and second planes of orthogonal first and second directions in a stack along a third direction Z that is orthogonal to the first and second directions, the first level including the conductive metal feature.

17. The support structure of claim 10, wherein the support structure is a lead frame that includes the conductive metal feature.

18. A method of fabricating an electronic device, the method comprising:
forming bond wires on an attachment location of a conductive feature of a support structure;
soldering a conductive terminal of a semiconductor die to the attachment location of the conductive feature over at least some of the bond wires.

19. The method of claim 18, further comprising roughening a surface of the attachment location of a conductive feature before forming the bond wires.

20. The method of claim 18, wherein forming the bond wires includes overlapping first and second ones of the bond wires.
